(19) United States
(12) Patent Application Publication
(10) Pub. No.: US 2014/0342471 A1
(43) Pub. Date: Nov. 20, 2014

(54) Variable Doping Of Solar Cells

(71) Applicant: Varian Semiconductor Equipment Associates, Inc., Gloucester, MA (US)

(72) Inventors: Nicholas P.T. Bateman, Reading, MA (US); Manav Sheoran, Beverly, MA (US)

(73) Assignee: Varian Semiconductor Equipment Associates, Inc., Gloucester, MA (US)

(21) Appl. No.: 13/897,644

(22) Filed: May 20, 2013

(51) Int. Cl. H01L 21/66; H01L 21/67; H01L 21/265

(52) U.S. Cl. CPC H01L 22/12; H01L 21/26513; H01L 21/67288; Y10S 901/02
USPC 438/5; 118/712; 901/2

(57) ABSTRACT

A system and method for determining the edge or region where a saw first enters a silicon brick, and using this information to process this region differently is disclosed. This region, referred to as the saw entry region, may be thinner, or have a rougher texture than the rest of the substrate. This difference may impact the substrate's ultimate performance. For example, if the substrate is processed as a solar cell, the performance of the saw entry region may be suboptimal.

### FIELD

This application relates to a method of determining the properties of an unprocessed substrate, and adjusting the subsequent processing of the substrate based on that property.

### BACKGROUND

Solar cells typically utilize a p-n junction to separate electron-hole pairs that are created by photons penetrating the substrate. This may be achieved by disposing a p-type region adjacent to an n-type region. Traditionally, one of these regions, such as the p-type region, may be provided through the use of a previously doped bulk material. For example, the bulk silicon used to create a solar cell may be p-type silicon. Methods of creating bulk silicon with n-type or p-type dopants incorporated therein are well known in the art. One surface of this bulk p-type silicon is then doped with n-type ions to create a n-type region, or emitter, adjacent to the remainder of the p-type bulk silicon.

Variations in the sheet resistance of the emitter region, may have an adverse impact on the efficiency of the solar cell. In some instances, the sheet resistance of the emitter region may vary across the surface of the substrate. In other words, the sheet resistance of the emitter may be noticeable different in one portion of the substrate. This non-uniformity may be caused by variations in the texture of the underlying substrate and may have a deleterious effect on the performance of a solar cell produced using such a substrate.

Therefore, an improved method of processing a substrate, using information related to the underlying substrate's properties, is needed.

### SUMMARY

A system and method for determining the edge or region where a saw first enters a silicon brick, and using this information to process this region differently is disclosed. This region, referred to as the saw entry region, may be thinner, or have a rougher texture than the rest of the substrate. This difference may impact the substrate's ultimate performance. For example, if the substrate is processed as a solar cell, the performance of the saw entry region may be suboptimal.

In one embodiment, a method of processing a substrate is disclosed, which comprises determining which region of the substrate was first entered by a saw when the substrate was separated from a silicon brick, the edge defined as a saw entry region; and processing the saw entry region of a surface of the substrate differently than a remainder of the surface of the substrate. For example, the dose of ions implanted may be altered based on this determination.

In another embodiment, a method of processing a substrate to form a solar cell is disclosed. This method comprises determining a region of the substrate that was first entered by a saw when the substrate was separated from a silicon brick, the region defined as a saw entry region, wherein the determining step is based on a measurement of at least one of conductivity, thickness or texture; rotating the substrate such that the saw entry region has a predetermined orientation; transferring the substrate with the predetermined orientation into an ion implanter; and implanting a first dose of ions into the saw entry region of a surface of the substrate, greater than a second dose implanted into other portions of the surface of the substrate, to compensate for characteristics of the saw entry region.

In another embodiment, an apparatus is disclosed, comprising a detection station, configured to detect a region of a substrate that was first entered by a saw when the substrate was separated from a silicon brick, the region defined as a saw entry region; an ion implanter; a substrate handling system, comprising a rotating robot, to move the substrate from the saw entry region detection station to the ion implanter; and a controller configured to rotate the substrate using the rotating robot such that the substrate enters the ion implanter with the saw entry region in a predetermined orientation.

### BRIEF DESCRIPTION OF THE FIGURES

For a better understanding of the present invention, reference is made to the accompanying drawings, which are incorporated herein by reference and in which:

FIG. 1 shows the effect of a saw on the sheet resistance of a substrate;

FIG. 2 shows a system which may be used in accordance with one embodiment;

FIG. 3 shows a graph of possible scanning speed profiles;

FIG. 4 shows the sheet resistance of the substrate implanted using the profiles of FIG. 3;

FIG. 5 shows a flowchart in accordance with one embodiment;

FIG. 6 shows one embodiment of processing a batch of substrates simultaneously; and

FIG. 7 shows a second embodiment of processing a batch of substrates.

### DETAILED DESCRIPTION

Multi-crystalline silicon (mc-Si) is typically grown as large blocks, known as bricks. A saw is then used to cut thin substrates from the larger brick. The saw may be a wire saw that enters the brick along one edge and proceeds through the entirety of the brick. Acidic texture is typically used to improve the reflectance of mc-Si solar cells. Acid is applied to an unprocessed substrate after it has been separated from the brick using the saw. The damage caused by the saw creates the initial texture pattern on the substrate. The acid then further textures the substrate.

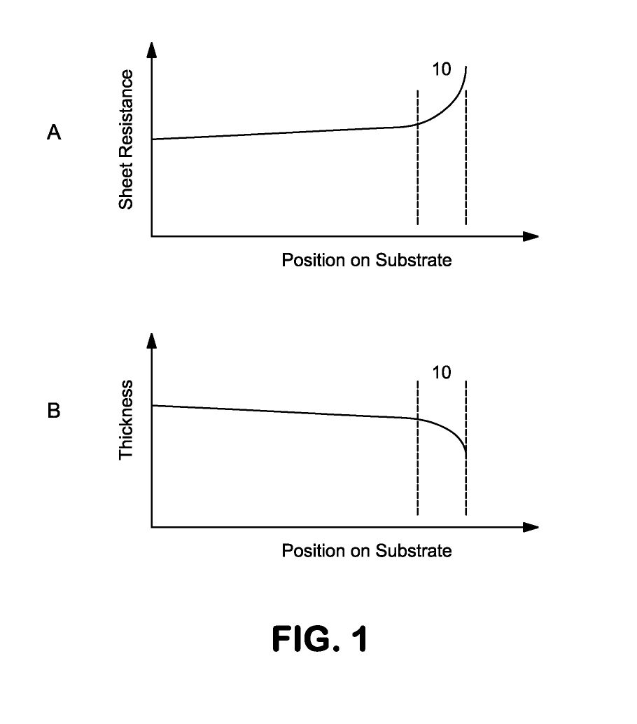

After texturing, ion implantation may be performed to create the emitter region. After ion implantation, the emitter region of a silicon substrate may have non-uniform sheet resistance across its surface. For example, one edge may have noticeable higher sheet resistance than the rest of the substrate. FIG. 1A shows an exemplary representation of the changes in the sheet resistance of an emitter region as a function of position on the substrate. FIG. 1B shows the thickness of this substrate. Note that the higher sheet resistance correlates to the thinner portion of the substrate. As can be seen, the sheet resistance increases along one edge of the substrate, which is thinner than the rest of the substrate. These increases in sheet resistance negatively impact cell efficiency.

It has been discovered that this non-uniformity of sheet resistance may be due to non-uniform texturing. This non-uniformity in the texturing has been found to be correlated with the wafer thickness. Further investigation reveals that the damage caused by the saw is not uniform across the substrate. Specifically, the edge or end of the brick where the saw first enters the silicon may cause the substrates that are cut to be thinner in that region than the rest of the substrate. Throughout this disclosure, the term “saw entry region” is used to describe the portion of the substrate where the saw first entered the brick. In other words, when the saw enters and passes through the brick, it creates substrates, where these substrates may have a region that has different characteristics than the rest of the substrate. This region of the substrate correlates to the edge where the saw first entered the brick. When the saw actually enters the brick, it is recognized that the saw creates the unevenness in the cut substrates. Thus, the edge where the saw first enters the brick corresponds to a region of the substrate referred to as the “saw entry region”. The saw entry region may also include the region proximate to the edge where the saw first entered, and include portions where the thickness or texture of the substrate is different from the rest of the substrate. For example, in FIG. 1B, the region 10 may be considered the saw entry region. As stated above, this saw entry region may also have rougher texture. This may be due to the change in the size of the grit as the saw progresses through the brick. Thus, the saw entry region may have different properties than the rest of the substrate. This saw entry region may be thinner than the rest of the substrate. In some tests, a reduction in thickness of nearly 8% has been measured. For example, in one test, a reduction in thickness from about 183 μm to about 170 μm was observed. In addition, this saw entry region may have a rougher surface than the rest of the substrate. These differences are maintained through the subsequent acidic texturing process.

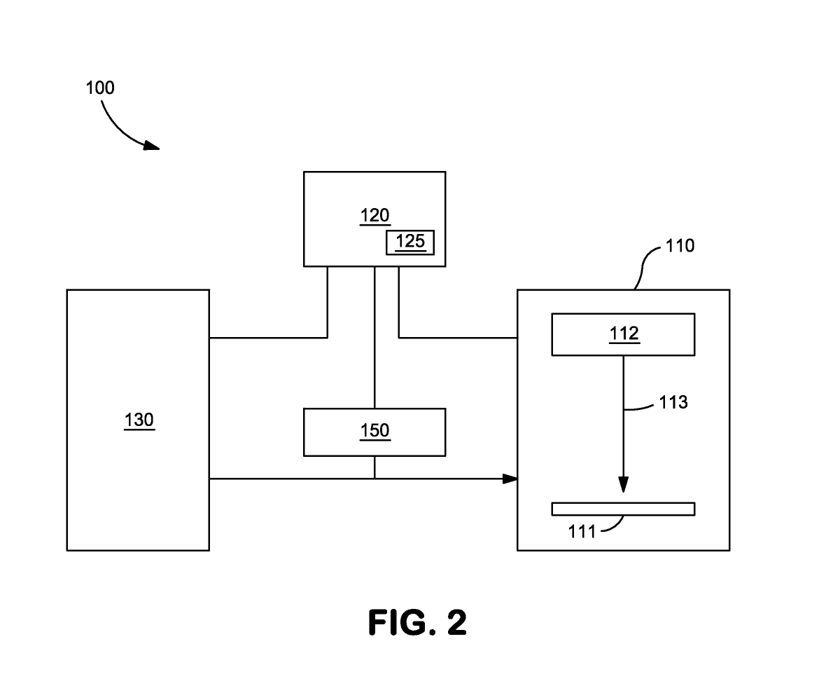

Therefore, by determining which edge of the substrate corresponds to the edge of the brick that was first entered by the saw, it is possible to compensate for these effects. FIG. 2 shows a system which may be used in accordance with one embodiment. The system 100 includes an ion implanter 110, which is used to introduce ions into the substrate. The ion implanter 110 may include an ion beam generator 112, and a platen 111 to hold a substrate. The ion beam generator 112 is configured to generate the ion beam 113 and direct it towards a front surface of the substrate. The ion beam generator 112 may include many components known to those skilled in the art, such as an indirectly heated cathode ion source, an RF ion source, an extraction assembly positioned proximate an extraction aperture of the ion source, a mass analyzer, acceleration/deceleration lenses, etc. to provide the ion beam 113 having desired characteristics, such as beam current, uniformity, and energy levels. The ion implanters 110 may also have a scanner to move the substrate through the path of the ion beam 113. In some embodiments, the scanner can move in all three axes. In other embodiments, the scanner can move in two perpendicular axes which are orthogonal to the path of the ion beam 113. Such scanners are well known in the art.

The ion implanter 110 has been described as a beam line or flood ion implanter but a plasma doping implanter may also be utilized to treat the substrate. Those skilled in the art will recognize a plasma doping implanter positions the substrate in a processing chamber where plasma is generated.

The system 100 also includes a saw entry region detection station 130, which is used to determine the edge first entered by the saw. For example, the saw entry region detection station 130 may measure a property of the substrate to detect the saw entry region. In one embodiment, the saw entry region detection station 130 may measure the thickness of the substrate at various locations across its surface to determine the saw entry region. Thickness may be measured in a variety of ways. For example, this may be performed by optical measurement using a CCD camera to determine substrate thickness. In another embodiment, thickness is determined by determining the distribution of mass across the substrate. For example, a comparison of the center of gravity to the geometric center may be used to determine the saw entry region, which is lighter than the other edges.

In another embodiment, an eddy current detector is used. In this embodiment, a coil carrying current is disposed near the substrate, so as to induce eddy current in the substrate. One or more probes are then used to measure this eddy current at different points along the substrate. Based on these measurements, the least conductive portion of the substrate can be determined. This least conductive portion may be determined to be the saw entry region.

In other embodiments, the saw entry region detection station may determine the roughest portion of the substrate. For example, profilometry or reflectance techniques may be employed to determine the roughest portion of the substrate. This roughest edge may be determined to be the saw entry region.

While the saw entry region detection station 130 may be used to measure a property of the substrate that is altered by the saw entry, other embodiments are also possible. For example, an indication of the saw entry region may be created when the substrate is cut. For example, a fiducial may be placed on the saw entry region immediately after the saw cut. The saw entry region detection station 130 would then use optical means to detect the fiducial.

In another embodiment, the substrate may be imaged immediately after the saw cut. The grain pattern at the saw entry region is then stored. The saw entry region detection station 130 then compares this stored grain pattern to an optical image of the substrate to determine the saw entry region.

Other methods of determining the saw entry region of the substrate may also be employed by the saw entry region detection station 130. Having determined the saw entry region, several different subsequent steps can be performed to process this saw entry region in order to equalize the sheet resistance of the emitter for the entire substrate.

The system 100 may also include automated substrate handling equipment 150 for transferring substrates between the measurement station 130 and the platen 111, which may include robots, conveyor belts, or other systems known to those skilled in the art. The substrate enters the measurement station 130 prior to entering the ion implanter 110. The automated substrate handling equipment 150 may include a rotating robot, which may be used to orient the substrates such that the saw entry regions are all aligned consistently.

The system 100 also includes a controller 120 in communication with the saw entry region detection station 130, the automated substrate handling equipment 150 and the ion implanter 110. The controller 120 can be or may include a general-purpose computer or network of general-purpose computers that may be programmed to perform desired input/output functions. The controller 120 can also include other electronic circuitry or components, such as application specific integrated circuits, other hardwired or programmable electronic devices, discrete element circuits, etc. The controller 120 may also include communication devices, data storage devices, and software. The controller 120 is in communication with a non-transitory medium, such as a storage element 125. This storage element 125 contains instructions, which when executed by the controller 120, perform the steps and operations described herein. The controller 120 may receive input signals from a variety of systems and components such as the ion beam generator 112, and the measurement station 130 and provide output signals to each to control the same.

In operation, the substrate is transferred to the saw entry region detection station 130, such as by the substrate handling equipment 150. Thereafter, the controller 120 performs a saw entry region detection technique, such as any of those described above. Based on the detection technique, the saw entry region can be determined. The orientation of this saw entry region may then stored by the controller 120 in storage element 125. As the substrate is removed from the saw entry region detection station 130, the controller 120 instructs the substrate handling equipment 150 to rotate the substrate to orient the saw entry regions of all of the substrates before these substrates enter the ion implanter 110.

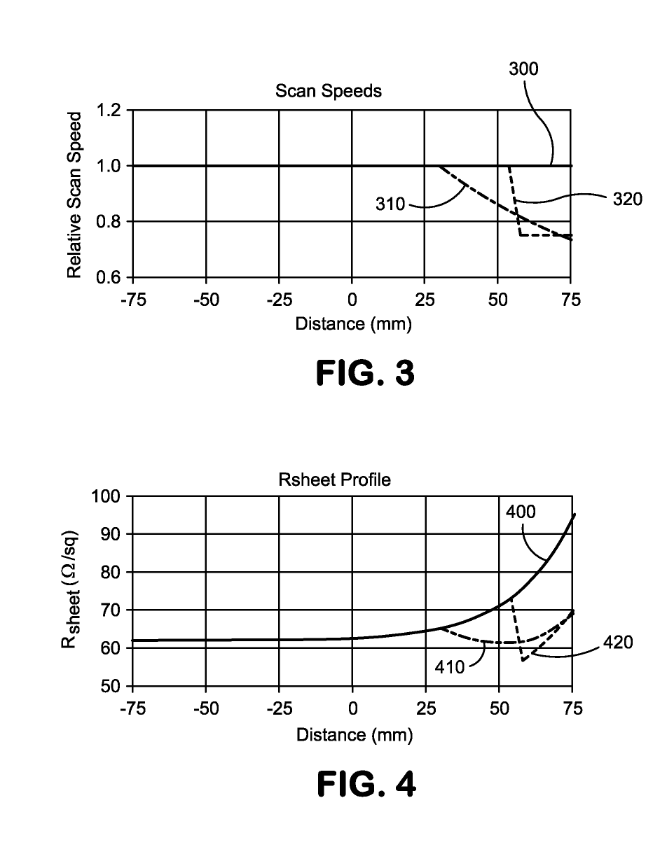

The ion implanter 110 can then be configured to apply additional dose to the saw entry region to compensate for its higher sheet resistance due to its relative thinness and roughness. For example, the ion implanter may utilize a scanner to move the substrate in the path of the ion beam 113. The scanner may be slowed when the saw entry region is in the path of the ion beam 113. This allows additional ions to be implanted in this saw entry region of the substrate. For example, FIG. 3 shows variation in scan speeds that can be used. FIG. 4 shows the sheet resistance achieved using the scan speed profiles shown in FIG. 3. For example, line 300 (FIG. 3) shows a traditional scan, where the scan speed is constant across the entire surface of the substrate. Line 400 (FIG. 4) shows the corresponding sheet resistance achieved using this scanning profile. Note that the sheet resistance of the substrate increases significantly at one edge, similar to that shown in FIG. 1A. Line 310 shows a first variable scanning profile where the scanning speed is constant through most of the surface and then decreases linearly near the saw entry region. Line 410 (FIG. 4) shows the resulting sheet resistance when this scanning speed profile is used. Line 320 (FIG. 3) shows a second variable scanning profile where the scanning speed is constant through most of the surface and then decreases to another slower speed near the saw entry region. Line 420 (FIG. 4) shows resulting sheet resistance when this scanning speed profile is used. Note that other scanning speed profiles can be used to increase the dose near the saw entry region to achieve a more uniform sheet resistance. For example, the scanning profile may attempt to create an inverse relationship of thickness, where the speed of the scanner is slower as the substrate gets thinner. It should be noted that even the simple profiles shown in lines 310 and 320 cause a dramatic improvement in sheet resistance uniformity.

While changing scanning speed can be used to vary the dose at the saw entry region, other techniques can also be used. For example, in a pulsed beam architecture, the pulse rate of the ion beam can be increased under the region near the saw entry region. In another embodiment, the extraction or beam optics can be modified to increase beam current. In other embodiments, a mask may be used to cover most of the substrate while additional ions are implanted into the region near the saw entry region. In yet another embodiment, a first uniform dose can be applied to the entire substrate. A second patterned implant may be subsequently applied to the region near the saw entry region. Of course, other methods of applying a greater dose to one particular region of a substrate are also possible and are within the scope of the disclosure.

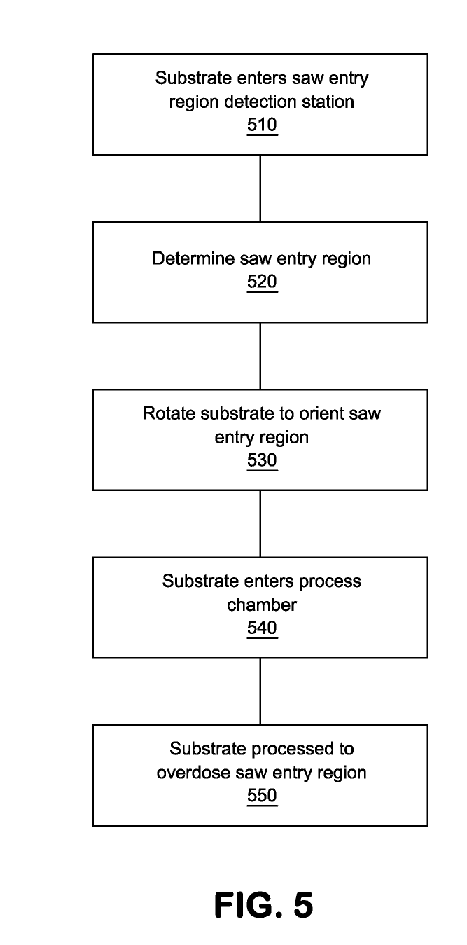

FIG. 5 shows a flowchart according to one embodiment. As shown in step 510, a substrate enters the saw entry region detection station 130. A technique is then performed to determine where the saw first entered the brick, as shown in step 520. As described above, various techniques may be used to detect this saw entry region.

The controller then instructs the substrate handling equipment to rotate the substrate to properly orient the saw entry region, as shown in step 530.

Later, the substrate enters a process chamber, as shown in step 540. This process chamber may be ion implanter 110. At this time, the substrate is processed based on this saw entry region detection, as shown in step 550. This processing may include increased dosing of the substrate in the region near the saw entry region. Stated differently, the system processes the saw entry region differently than the rest of the substrate. For example, the rest of the substrate may be implanted with a first dose, while the saw entry region is implanted with a second dose, greater than the first dose. In one embodiment, the ion implantation is used to form an emitter region of a solar cell, where the saw entry region is implanted with a dose greater than that applied to the rest of the substrate.

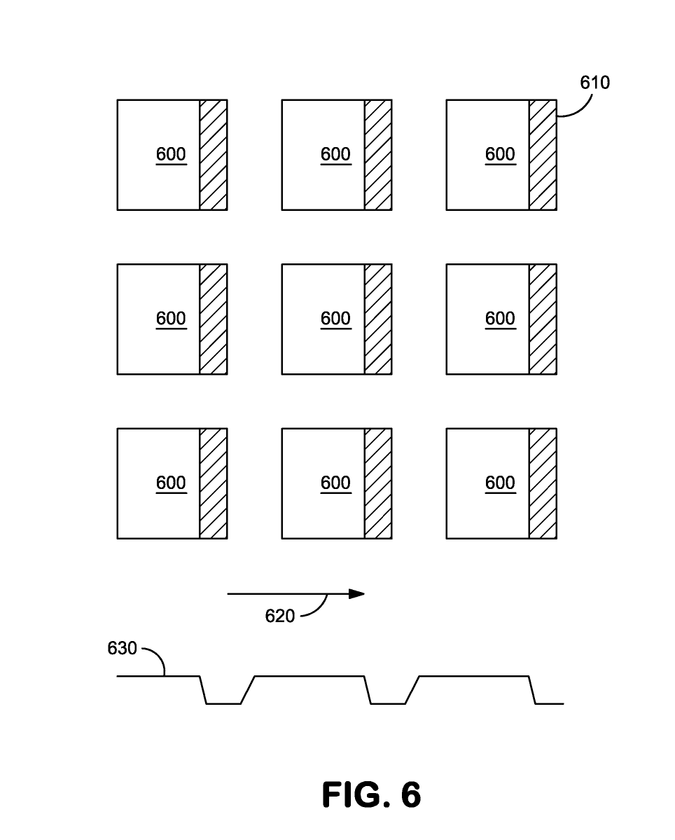

The above description describes a process where each substrate is implanted individually. In some embodiments, a set of substrates, also known as a batch, are implanted simultaneously. For example, a batch of the substrates 600 may be arranged in an array, as shown in FIG. 6. In this array, all substrates 600 in a vertical column enter the path of the ion beam simultaneously. Substrates 600 arranged in a particular horizontal row are processed sequentially by the ion implanter 110. In this embodiment, all of the saw entry regions 610 (illustrated in FIG. 6 with hash marks) are oriented along the scanning direction 620. Graph 630 shows a representative scanning speed profile that shows how the scanner adapts to the saw entry regions 610. As the substrates 600 move, the scanning slows when the saw entry region 610 of a particular column reaches the path of the ion beam. As the saw entry region is implanted, the scanning returns to nominal speed. Note that this embodiment requires the scanner to change speeds twice for each column of substrates 600.

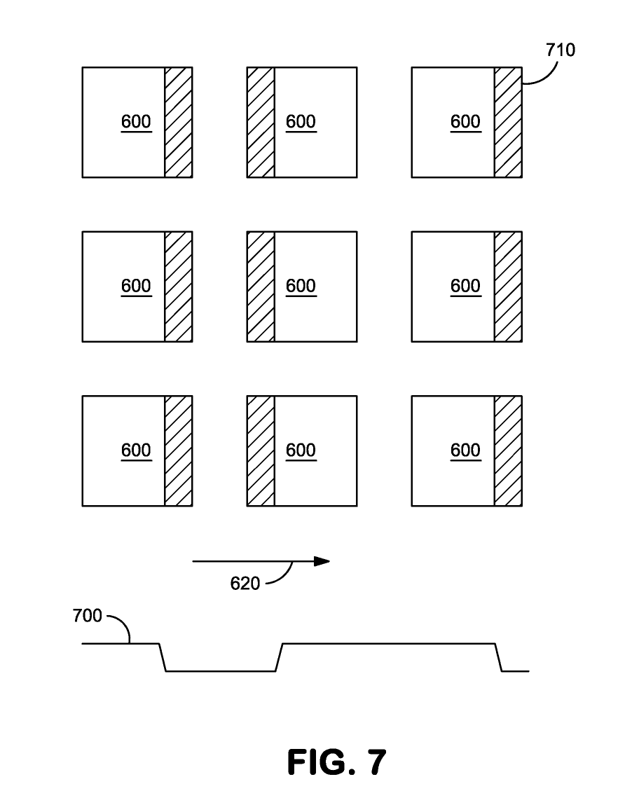

FIG. 7 shows another embodiment intended to improve efficiency and throughput. In this embodiment, the controller 120 orients the saw entry regions 710 of the substrates 600 such that saw entry regions 710 of substrates 600 in two columns are adjacent. In this way, the speed of the scanning only changes once per column, as shown in graph 700, rather than twice as described in FIG. 6. The orientation of saw entry regions for all substrates 600 in a vertical column is the same. In this way, when the ion beam reaches this vertical column, all substrates 600 in that column may be processed simultaneously, since the saw entry regions 710 of each are aligned.

Further, the above disclosure describes a system and method where the saw entry region is identified and, once identified, processed accordingly. This may assume that the thickness and texture of all saw entry regions are sufficiently similar so a single process to compensate for non-uniformity is applicable to all saw entry regions. However, in some embodiments, properties of saw entry regions of different substrates may differ from each other, either in terms of thickness, texture or both. Thus, a single process to compensate for non-uniformity of all saw entry regions may be inadequate. In these embodiments, several different process steps may be undertaken.

In systems where substrates are processed in the ion implanter 110 individually, the scanning speed or other mechanism to increase the dose in the region near the saw entry region may be tailored specifically to that substrate. For example, the saw entry region detection station 130 may measure the thickness of the saw entry region, and the controller 120 may calculate an optimal dose for that thickness to improve the uniformity of the emitter. This optimal dose can then be converted to a scanning speed, ion beam current, or another parameter. The substrate is then processed accordingly. For example, the saw entry region region may receive this optimal dose, while the rest of the substrate receives the nominal dose, as described above.

When substrates are processed in batches, as shown in FIGS. 6 and 7, several techniques may be employed. In one embodiment, after the saw entry region detection station 130, the substrates are then sorted by the controller 120 into groupings having similar saw entry region properties. Substrates having similar saw entry region properties are then arranged in a column such that these are processed simultaneously, as described above. In the embodiment of FIG. 7, substrates having similar saw entry region properties may be arranged in two adjacent columns.

In other embodiments, the controller 120 stores the saw entry region properties of each substrate in its storage element 125. When the substrates are arranged in arrays, as shown in FIG. 6, the controller 120 retrieves the properties for all substrates in a given column. The controller then performs some function to determine a batch property for that column. For example, the controller 120 may average the thicknesses of all substrates in a column to generate the batch column thickness. In another embodiment, the controller 120 may select the thinnest saw entry region and utilize that as the batch column thickness. Similar functions can be performed based on texture as well.

Once the batch property of a particular column is determined, this value is converted to an optimal dose, which can be implemented by varying scanning speed, ion beam current or some other parameter. Every substrate in a particular column is then processed in accordance with this batch column value.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A method of processing a substrate, comprising:
determining which region of said substrate was first entered by a saw when said substrate was separated from a silicon brick, said edge defined as a saw entry region; and
processing said saw entry region of a surface of said substrate differently than a remainder of said surface of said substrate.

2. The method of claim 1, wherein said saw entry region of said substrate is thinner than other portions of said substrate.

3. The method of claim 1, wherein said saw entry region of said substrate has rougher texture than other portions of said substrate.

4. The method of claim 1, wherein said saw entry region of said substrate is less conductive than other portions of said substrate.

5. The method of claim 1, wherein said processing comprising implanting ions and wherein said saw entry region receives a greater dose of ions than other portions of said surface of said substrate.

6. The method of claim 5, wherein a scanner is used to move said substrate through an ion beam, and said greater dose is achieved by lowering a scanning rate of said scanner when said saw entry region is in a path of said ions.

7. The method of claim 1, wherein after said determining step, said substrate is rotated such that said saw entry region has a predetermined orientation prior to said processing step.

8. The method of claim 1, wherein a plurality of said substrates are processed simultaneously, and wherein after said determining step has been performed for each of said substrates, said substrates are rotated so that said saw entry region of each of said plurality of said substrates has a predetermined orientation prior to said processing step.

9. The method of claim 1, further comprising measuring a resistance of said saw entry region, and wherein said processing comprising implanting ions, wherein said saw entry region receives a greater dose of said ions than other portions of said surface of said substrate wherein said dose of said ions is based on said measured resistance.

10. The method of claim 5, wherein said ion implanter utilizes a mask, and a first uniform dose is applied to said surface and a second patterned implant is applied to said saw entry region.

11. A method of processing a substrate to form a solar cell, comprising:
determining a region of said substrate that was first entered by a saw when said substrate was separated from a silicon brick, said region defined as a saw entry region, wherein said determining step is based on a measurement of at least one of conductivity, thickness or texture;
rotating said substrate such that said saw entry region has a predetermined orientation;
transferring said substrate with said predetermined orientation into an ion implanter; and
implanting a first dose of ions into said saw entry region of a surface of said substrate, greater than a second dose implanted into other portions of said surface of said substrate, to compensate for characteristics of said saw entry region.

12. The method of claim 11, wherein said determining step is performed using an eddy current detector.

13. The method of claim 11, wherein a scanner is used to move said substrate through a path of said ions, wherein a scanning rate is reduced when said saw entry region is in said path of ions.

14. The method of claim 11, wherein said determining step is performed prior to said implanting.

15. An apparatus comprising:
a saw entry region detection station, configured to detect a region of a substrate that was first entered by a saw when said substrate was separated from a silicon brick, said region defined as a saw entry region;
an ion implanter;
a substrate handling system, comprising a rotating robot, to move said substrate from said saw entry region detection station to said ion implanter; and
a controller configured to rotate said substrate using said rotating robot such that said substrate enters said ion implanter with said saw entry region in a predetermined orientation.

16. The apparatus of claim 15, wherein said detection station comprises an eddy current detector.

17. The apparatus of claim 15, wherein said detection station comprises a substrate thickness measurement device.

18. The apparatus of claim 15, wherein said detection station comprises a surface roughness detector.

19. The apparatus of claim 15, wherein said ion implanter utilizes a scanner to move said substrate in a path of ions, wherein said scanner scans more slowly when said saw entry region is in said path of ions.

20. The apparatus of claim 15, wherein a plurality of said substrates are implanted by said ion implanter simultaneously, wherein said controller rotates each of said plurality of said substrates such that said saw entry region of each of said plurality of said substrates are all in said predetermined orientation, such that all of said saw entry regions are in a path of said ions simultaneously.
